(19) United States
(12) Patent Application Publication
(10) Pub. No.: US 2007/0068729 A1
(43) Pub. Date: Mar. 29, 2007

(54) Speaker with vibration-proof design

(75) Inventor: Yi-Jen Chen, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/527,379

(22) Filed: Sep. 27, 2006

(30) Foreign Application Priority Data
Sep. 29, 2005 (TW) 094133988

(51) Int. Cl. A47B 81/06; H05K 5/00

(52) U.S. Cl. 181/199; 181/148

(57) ABSTRACT

A speaker includes a sound box, a base installed below the sound box for supporting the sound box, and a cushioning component installed between the sound box and the base for absorbing vibration generated by a speaker unit. A stand is installed below the base for supporting the sound box above the ground.

### BACKGROUND OF THE INVENTION

1. Field of the Invention

The present invention relates to a speaker, and more particularly, to a speaker with vibration-proof design.

2. Description of the Prior Art

The sound pressure generated by a bass speaker usually makes the bass speaker vibrate. The vibration can be transmitted to a structure supporting the bass speaker resulting in noise so as to reduce the sound quality of the bass speaker. The conventional solutions for solving the above-mentioned problem are as follows. One is increasing the weight of a sound box of the bass speaker, such as utilizing material of high density such as thick plank, so as to absorb the vibration and prevent the vibration from being transmitted. However the disadvantage is that the appearance of the speaker cannot have a streamlined or compact shape due to the size and shape of plank material. Besides, the joints of the planks have to be glued and the speaker can only be assembled after the glue hardens so that the production speed of the sound box will be reduced. The second solution is reducing the sound pressure outputted by the bass speaker so as to reduce the vibration. However this limits the output power of the bass speaker. The third solution is avoiding the resonant frequency of the sound box by a circuit design of an amplifier. However when utilizing different amplifiers to match the speaker, the vibration problem still exists due to different amplifiers with different circuit designs. In conclusion, there is a need to find a solution to reduce the noise due to vibration, while maintaining flexibility in appearance and the ability to use different amplifiers for the speaker.

### SUMMARY OF THE INVENTION

It is therefore a primary objective of the claimed invention to provide a speaker with vibration-proof design for solving the above-mentioned problem.

According to the claimed invention, a speaker includes a sound box, a base installed below the sound box for supporting the sound box, and a cushioning component installed between the sound box and the base for absorbing vibration generated by a speaker unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a speaker according to the present invention.

FIG. 2 is an exploded diagram of the speaker of FIG. 1 according to the present invention.

### DETAILED DESCRIPTION

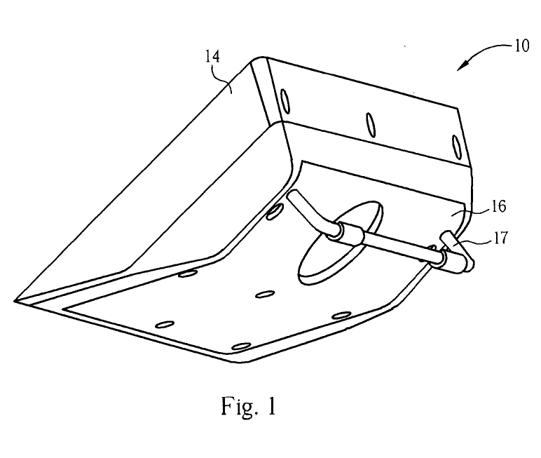

Please refer to FIG. 1. FIG. 1 is a schematic diagram of a speaker 10 according to the present invention. The speaker 10 can be a bass speaker. The speaker 10 includes a sound box 14. The sound box 14 can be a plastic sound box with a curved surface. The speaker 10 further includes a base 14 installed below the sound box 14 for supporting the sound box 14, and a stand 17 installed below the base 16 for supporting the sound box 14. The stand 17 can be a steel stand.

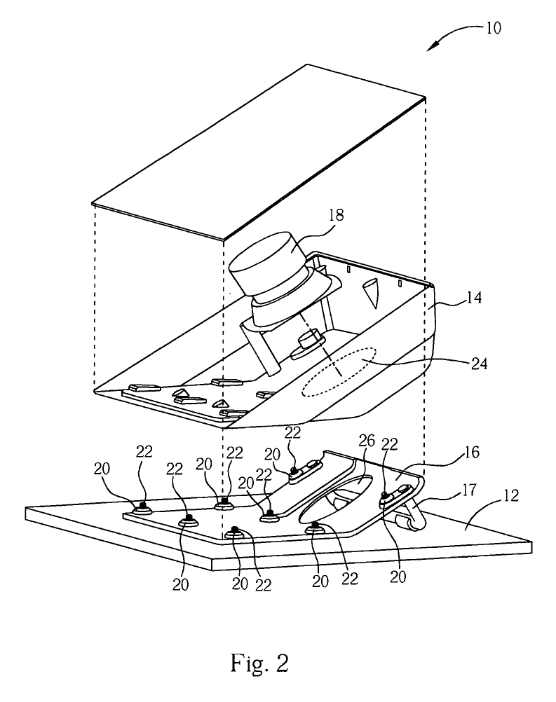

Please refer to FIG. 2. FIG. 2 is an exploded diagram of the speaker 10 of FIG. 1 according to the present invention. The stand 17 of the speaker 10 can support the sound box 14 on a surface 12 such as a floor, the ground, a table, etc. The speaker 10 further includes a speaker unit 18 installed inside the sound box 14 for transforming sound signals into sound waves, and a plurality of cushioning components 20 installed between the sound box 14 and the base 16. The cushioning component 20 can be fixed on the base 16. The cushioning component 20 can be a silica-gel absorber, a spring, or other absorbers with damping or elasticity. The speaker 10 further includes a plurality of fastening components located in positions corresponding to the plurality of cushioning components 20 for fastening the sound box 14 and the base 16 so as to clamp the plurality of cushioning components 20 between the sound box 14 and the base 16. The fastening component can be a screw. A first opening 24 is located in a position on a bottom of the sound box 14 corresponding to a sound hole of the speaker unit 18, and a second opening 26 is located in a position on the base 16 corresponding to the first opening 24. The sound waves generated by the speaker unit 18 of the speaker 10 can be outputted through the first opening 24 and the second opening 26.

Because the cushioning components 20 separate the sound box 14 containing the speaker unit 18 from the base 16, the cushioning components 20 fixed on the base 16 can absorb vibrations due to sound pressure (vibrations due to sound pressure can also be absorbed by the sound box 14 itself) so as to prevent vibrations from being transmitted to the surface 12 via the sound box 14, the base 16, and the stand 17 thereby producing noise. Additionally, the material, number, or positions of the cushioning components 20 can be adjusted for adjusting a damping coefficient or an elasticity coefficient of the cushioning components 20 so as to adjust an equivalent damping coefficient or elasticity coefficient of the speaker 10. Therefore, the resonant frequency of the speaker 10 can be adjusted to avoid matching the frequency of the output sound signals. Thus, there is no need to adjust the circuit of every amplifier for avoiding the resonant frequency of the speaker 10 when providing different amplifiers. The cushioning components 20 can be arranged for adjusting the resonant frequency of the speaker 10 so as to avoid the frequency of the output sound signals.

In contrast to the conventional speaker, the speaker according to the present invention utilizes the cushioning components 20 installed between the sound box and the base so that vibrations generated by the speaker unit can be absorbed by the cushioning components 20 or by the sound box itself. This can prevent vibrations from being transmitted to the ground or other supporting surface to produce noise. Additionally, the speaker according to the present invention can include a sound box with a curved surface of light-weight material, such as plastic so that the weight of the speaker is reduced and the appearance of the speaker can be designed as desired (curved, streamlined, etc). In addition, the cushioning components can be arranged for adjusting the resonant frequency of the speaker so as to avoid the frequency of the output sound signals. There is no need to adjust the circuit of every amplifier to avoid the resonant frequency of the speaker when providing different amplifiers. In conclusion, the present invention provides a solution for reducing noise due to vibration while maintaining flexibility for appearance and allowing utilization of different amplifiers for the speaker.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A speaker comprising:
a sound box;
a base installed below the sound box for supporting the sound box; and
a cushioning component installed between the sound box and the base for absorbing vibration generated by a speaker unit.

2. The speaker of claim 1 wherein a stand is installed below the base for supporting the sound box above a ground.

3. The speaker of claim 2 wherein the stand is a steel stand.

4. The speaker of claim 1 wherein a first opening is located at a position on a bottom of the sound box corresponding to a sound hole of the speaker unit and a second opening is located at a position on the base corresponding to the first opening.

5. The speaker of claim 1 wherein the cushioning component is a silica-gel absorber.

6. The speaker of claim 1 wherein the cushioning component is a spring.

7. The speaker of claim 1 further comprising a fastening component for fastening the sound box and the base.

8. The speaker of claim 7 wherein the fastening component is a screw.

9. The speaker of claim 1 wherein the sound box is a plastic sound box with a curved surface.

10. The speaker of claim 1 being a bass speaker.
